(19) United States
(12) Patent Application Publication
(10) Pub. No.: US 2023/0335770 A1
(43) Pub. Date: Oct. 19, 2023

(54) REDOX FLOW BATTERY WITH RAMAN SPECTROMETER

(71) Applicant: RAYTHEON TECHNOLOGIES CORPORATION, Waltham, MA (US)

(72) Inventors: Timothy C. Davenport, East Hartford, CT (US); James Demetrios Saraidaridis, East Hartford, CT (US)

(21) Appl. No.: 17/721,509

(22) Filed: Apr. 15, 2022

(51) Int. Cl. H01M 8/18; G01R 31/382; G01R 31/378; G01N 21/65; H01M 8/0444; H01M 8/04186

(52) U.S. Cl. CPC H01M 8/188; G01R 31/382; G01R 31/378; G01N 21/65; H01M 8/04477; H01M 8/04186

(57) ABSTRACT

A redox flow battery includes a cell that has first and second electrodes and an ion-exchange layer there between, first and second circulation loops that are fluidly connected with, respectively, the first and second electrodes, first and second electrolyte storage tanks in, respectively, the first and second circulation loops, first and second electrolytes contained in, respectively, the first and second circulation loops, and a Raman spectrometer on at least one of the first or second circulation loops for determining a state-of-charge of at least one of the first or second electrolytes. The Raman spectrometer includes a laser source that is rated to emit a laser of a wavelength of 694 nanometers to 1444 nanometers.

### BACKGROUND

Flow batteries, also known as redox flow batteries or redox flow cells, are designed to convert electrical energy into chemical energy that can be stored and later released back into electrical energy when there is demand As an example, a flow battery may be used with a renewable energy system, such as a wind-powered system, to store energy that exceeds consumer demand and later release that energy when there is greater demand

A typical flow battery includes a redox flow cell that has a negative electrode and a positive electrode separated by an electrolyte layer, which may include a separator, such as an ion-exchange membrane. A negative fluid electrolyte (sometimes referred to as the anolyte or negolyte) is delivered to the negative electrode and a positive fluid electrolyte (sometimes referred to as the catholyte or posolyte) is delivered to the positive electrode to drive reversible redox reactions between redox pairs. Upon charging, the electrical energy supplied causes a reduction reaction in one electrolyte and an oxidation reaction in the other electrolyte. The separator prevents the electrolytes from freely and rapidly mixing but selectively permits ions to pass through to complete the redox reactions. Upon discharge, the chemical energy contained in the liquid electrolytes is released in the reverse reactions and electrical energy is drawn from the electrodes.

### SUMMARY

A redox flow battery according to an example of the present disclosure includes a cell that has first and second electrodes and an ion-exchange layer arranged there between, first and second circulation loops fluidly connected with, respectively, the first and second electrodes, first and second electrolyte storage tanks in, respectively, the first and second circulation loops, and first and second electrolytes contained in, respectively, the first and second circulation loops. There is a Raman spectrometer on at least one of the first or second circulation loops for determining a state-of-charge of at least one of the first or second electrolytes. The Raman spectrometer includes a laser source that is rated to emit a laser of a wavelength of 694 nanometers to 1444 nanometers.

In a further embodiment of any of the foregoing embodiments, the first electrolyte is a manganese electrolyte, the second electrolyte is a polysulfide electrolyte, and the Raman spectrometer is on the first circulation loop.

In a further embodiment of any of the foregoing embodiments, the wavelength is 1064 nanometers +/−1 nanometers.

In a further embodiment of any of the foregoing embodiments, the Raman spectrometer includes a probe on at least one of the first or second circulation loops.

In a further embodiment of any of the foregoing embodiments, the Raman spectrometer includes a control module that is configured to collect spectrometer data and determine from the spectrometer data the state-of-charge of at least one of the first or second electrolytes.

In a further embodiment of any of the foregoing embodiments, the control module is configured with calibration data that provides a correlation between the spectrometer data and concentration and state-of-charge.

In a further embodiment of any of the foregoing embodiments, the cell has an inlet side where the first and second circulation loops feed, respectively, the first and second electrolytes into the cell, an outlet side where the first and second electrolytes discharge from the cell into, respectively, the first and second circulation loops feed, and the Raman spectrometer is located on the outlet side of the cell.

In a further embodiment of any of the foregoing embodiments, the first electrolyte is a manganese electrolyte, the second electrolyte is a polysulfide electrolyte, the Raman spectrometer is on the first circulation loop, the Raman spectrometer includes a probe on the first circulation loop, the Raman spectrometer includes a laser source that is rated to emit a laser of a wavelength of 1064 nanometers +/−1 nanometers, the cell has an inlet side where the first and second circulation loops feed, respectively, the first and second electrolytes into the cell, the cell has an outlet side where the first and second electrolytes discharge from the cell into, respectively, the first and second circulation loops feed, and the probe is located on the outlet side of the cell.

A method according to an example of the present disclosure includes, during operation of a redox flow battery (RFB) to charge or discharge electrical energy, using a Raman spectrometer to collect spectrometer data from an electrolyte in the RFB. The Raman spectrometer includes a laser source that is rated to emit a laser of a wavelength of 694 nanometers to 1444 nanometers. The spectrometer data is compared to calibration data to determine a state-of-charge of the electrolyte, and based on the state-of-charge, it is determined whether to perform a rebalance on the RFB.

In a further embodiment of any of the foregoing embodiments, the RFB includes a cell that has first and second electrodes and an ion-exchange layer arranged there between, first and second circulation loops fluidly connected with, respectively, the first and second electrodes, and first and second electrolyte storage tanks in, respectively, the first and second circulation loops. The electrolyte is contained in the first circulation loop, and the Raman spectrometer is on the first circulation loop.

In a further embodiment of any of the foregoing embodiments, the Raman spectrometer includes a probe on at least one of the first or second circulation loops.

In a further embodiment of any of the foregoing embodiments, the cell has an inlet side where the first and second circulation loops feed, respectively, the first and second electrolytes into the cell, an outlet side where the first and second electrolytes discharge from the cell into, respectively, the first and second circulation loops feed, and the Raman spectrometer is located on the outlet side of the cell.

In a further embodiment of any of the foregoing embodiments, the electrolyte is a manganese electrolyte.

In a further embodiment of any of the foregoing embodiments, the wavelength is 1064 nanometers +/−1 nanometers.

The present disclosure may include any one or more of the individual features disclosed above and/or below alone or in any combination thereof.

The present disclosure may include any one or more of the individual features disclosed above and/or below alone or in any combination thereof.

### BRIEF DESCRIPTION OF THE DRAWINGS

The various features and advantages of the present disclosure will become apparent to those skilled in the art from the following detailed description. The drawings that accompany the detailed description can be briefly described as follows.

FIG. 1 illustrates an example redox flow battery.

### DETAILED DESCRIPTION

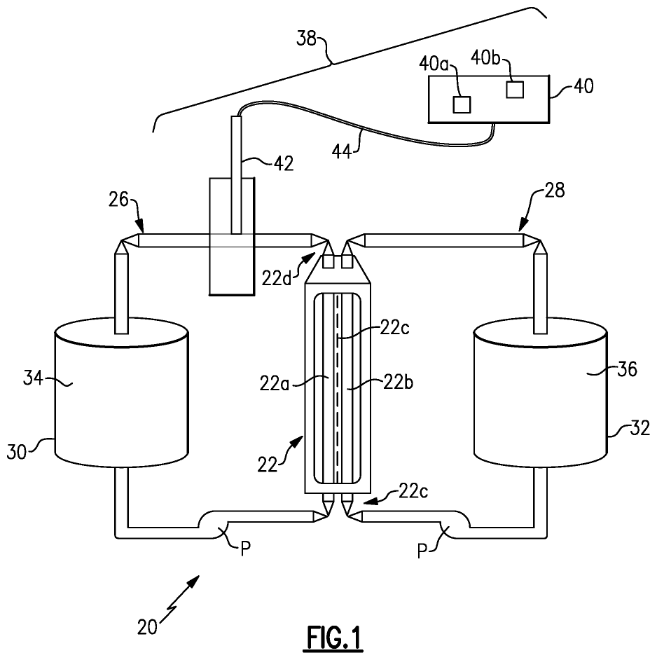

FIG. 1 schematically shows an example of a redox flow battery (“RFB”) 20. The RFB 20 includes a cell 22 (or multiple cells). The cell 22 includes a first electrode 22a, a second electrode 22b, and an ion-selective separator layer 22c between the electrodes 22a and 22b. For example, the electrodes 22a, 22b may be porous carbon structures, such as carbon paper or felt. The separator layers may be an ion-selective separator layer 22c, which permits selected ions to pass through to complete the redox reactions while electrically isolating the electrodes.

A first circulation loop 26 is fluidly connected with the first electrode 22a of the cell 22, and a second circulation loop 28 is fluidly connected with the second electrode 22b of the cell 22. As used herein, a “loop” refers to a continuous, closed circuit fluid passage. The first circulation loop 26 and the second circulation loop 28 may include respective electrolyte storage tanks 30 and 32. A first (negative) electrolyte solution 34 is contained in the first recirculation loop 26 (i.e., fluidly connected to the tank 30), and a second (positive) electrolyte solution 36 is contained in the second circulation loop 28 (i.e., fluidly connected to the tank 32). One or more pumps P may be provided in each of the loops 26/28 serve to circulate the electrolytes 34/36 through the loops 26/28. As will be appreciated, the terminology “first” and “second” is to differentiate that there are two distinct electrolytes/electrodes/loops. It is to be further understood that terms “first” and “second” are interchangeable in that the first electrolyte/electrode/loop could alternatively be termed as the second electrolyte/electrode, and vice versa.

A variety of different electrochemically active species can be used in the RFB 20. One example set of species for use in the first and second electrolytes 34/36 are manganese and sulfur, respectively. For instance, the first electrolyte 34 is a manganese electrolyte solution that is contained in the first recirculation loop 26 (i.e., fluidly connected to the tank 30), and the second electrolyte 36 is a polysulfide electrolyte solution that is contained in the second circulation loop 28 (i.e., fluidly connected to the tank 32). The first electrolyte solution 34 circulates through the first electrode 22a and the second electrolyte solution 36 circulates through the second electrode 22b. Although the examples herein may be described in context of manganese and polysulfide electrolyte solutions, it is to be understood that the examples are not limited to these and that other chemistries may also benefit.

The manganese in the first electrolyte solution 34 generally refers to permanganate or manganate salts in an alkaline, or basic, solution. For instance, the first electrolyte solution 34 may be 1M sodium permanganate (NaMnO₄) in 7.5 M sodium hydroxide (NaOH) or in another example 2M NaMnO₄ in 3M NaOH. The polysulfide in the second electrolyte solution 36 generally refers to salts of sulfur in a basic pH solution. For example, sodium polysulfides with the formula Na₂Sₓ, where x is 1 to 8, in sodium hydroxide. In one example, the second electrolyte solution 36 may be 1M Na₂Sₓ in 7.5M sodium hydroxide.

The following equations demonstrate example reactions in the cell 22, as well as the resulting electrode potential (E°) versus Standard Hydrogen Electrode (SHE) and Open Cell Voltage (OCV), which is defined herein as the difference between the standard electrode potentials of the two electrode reactions.

Negative: 2Na₂S₂↔Na₂S₄+2Na⁺+2e⁻

E°=−0.492 vs. SHE

Positive: 2NaMnO₄+2Na⁺+2e^{-↔2}Na₂MnO₄

E°=+0.564 vs. SHE

Net cell: 2Na₂S₂+2NaMnO₄↔Na₂S₄+2Na₂MnO₄

OCV=1.06 V

RFBs are susceptible to capacity losses for various reasons. Capacity loss is the decrease in the amount of electrical energy that can be stored in the electrolytes of the RFB (or provided from the electrolytes) in comparison to the maximum amount of electrical energy that the electrolytes can store (or provide) at an initial or theoretical maximum concentration. For example, ions may undesirably pass through the separator membrane, precipitate as solids that are unable to participate in the electrochemical reaction, or undergo self-discharge. Over time, such mechanisms may result in a concentration imbalance between the electrolytes. This concentration imbalance decreases the capacity of an individual electrolyte, and therefore the whole system, to store and discharge electrical energy. Measures are known for restoring the capacity. However, in order to effectively employ these measures, and do so only when necessary, the concentrations must first be determined.

RFB capacity loss can be diagnosed by monitoring a state-of-charge (“SOC”) of the electrochemically active species in the electrolytes. For example, the SOC of the electrolytes can be expressed in terms of the concentrations of the various oxidation states of the electrochemically active species, i.e., the concentration of oxidized form of species 1 divided by the sum of the concentrations of oxidized and reduced forms of species 1. Some active materials can have more than two oxidation states that are accessed in a given electrolyte. In an RFB system starting with known molar amounts of each active species in each electrolyte, a deviation in the SOCs measured between the opposing electrolytes indicates an imbalance and can drive accessible capacity loss. Alternatively, the overall active species concentration in the electrolytes (in both oxidized and reduced forms) can drift due to active species crossover, active species degradation, or solvent transfer between electrolytes, which can affect accessible capacity. In order to combat capacity loss, once the deviation in SOC or total concentrations between electrolytes reaches a preset threshold, measures may be taken to restore the capacity.

Various methods are known for monitoring concentrations and/or SOC. For example, observation of the open circuit voltage (“OCV”) can be used as an indirect indication of SOC. However, OCV only serves as an SOC of the system and is not indicative of the individual state of the two electrolytes since it only observes the complete battery voltage. Optical ultraviolet-visible absorbance spectroscopy can also be used, particularly for all-vanadium chemistries. Some chemistries, however, challenge the reliable use of ultraviolet-visible absorbance spectroscopy. For instance, a manganese electrolyte solution can degrade into solid oxide species (suspended in the electrolyte solution) that exhibit strong absorption bands that mask the absorbance profile of interest to identify the species, making accurate measurement difficult. For a polysulfide electrolyte solution, correlation between the polysulfide species and wavelength is concentration dependent and thus makes accurate measurement difficult.

In these regards, as discussed in further detail below, the RFB 20 includes a Raman spectrometer 38 for determining the SOC of at least one of the first or second electrolyte solutions 34/36. Unlike ultraviolet-visible absorbance spectroscopy, Raman spectroscopy relies on the interaction of light with molecular bond vibrations in the species compounds to produce Raman scatter, i.e. the re-emission of the excitation light. In the case of the species of interest in the RFB 20, such as the manganese and sulfur species, interference scatter from side products does not overwhelm the signal from the active species as much as interference absorbance does in UV-Vis spectroscopy such that Raman spectroscopy can more readily discriminate the different species.

In the illustrated example, the Raman spectrometer 38 includes a control module 40, a probe 42 on one or both of the circulation loops 26/28, and an optical cable 44 that connects the control module 40 and the probe 42. The control module 40 includes a laser source 40a and an analysis module 40b. The laser source 40a generates light over a very narrow wavelength range or at a substantially single wavelength (monochromatic).

The laser travels through the optical cable 44 and is emitted from the probe 42 into the electrolyte 34 or 36 of interest in the RFB 20, such as through a window on the piping that forms the loop 26/28. The laser interacts with the species molecules in the electrolyte 34 or 36, producing Raman scatter that is received back through the optical cable 42 to the analysis module 40b as spectrometer data. The analysis module 40b contains hardware (e.g., one or more microprocessors, memory, etc.), software, or both that is/are configured to analyze the spectrometer data and make a determination of the concentration and oxidation state of active materials, thereby allowing calculation of SOC for a single electrolyte. As is known generally in Raman spectroscopy, one or more filters may be present in the optical cable 42 and/or analysis module for reducing noise and conditioning the spectrometer data.

In the illustrated example, the Raman spectrometer 38 is shown on the first circulation loop 26. For instance, the cell 22 has an inlet side 22c where the electrolytes 34/36 in the first and second circulation loops 26/28 feed into the cell 22 and an outlet side 22d where the electrolytes 34/36 discharge from the cell into first and second circulation loops 26/28. The Raman spectrometer 38 is located on the outlet side 22d of the cell 22, i.e., downstream from the cell 22 but upstream of the storage tanks 30/32. It is to be appreciated that an additional Raman spectrometer 38 could be used on the second circulation loop 28, or the Raman spectrometer 38 could alternatively be on the second circulation loop 28 instead of the first circulation loop 26. Such a location permits high-accuracy measurement of the electrolytes 34/36, since the concentrations of species in the electrolytes 34/36 just as they exit the cell 22 will closely represent the concentrations inside the cell 22. Farther downstream, the electrolytes 34/36 are delivered into the storage tanks 30/32 and mix with prior “used” electrolyte that may have a slightly different concentration.

In general, the laser source 40a is rated to emit a laser of a wavelength in the range of 694 nanometers to 1444 nanometers. The wavelength that is selected for a particular implementation can be matched to the particular species to be analyzed in order to minimize noise, particularly fluorescent noise that might mask the Raman scatter wavelength bands of interest. For instance, lasers are typically available over a range of standard wavelengths. By testing the species of interest at a number of these wavelengths, one of ordinary skill in the art who has the benefit of this disclosure will be able to determine the wavelength or wavelength range that is best for their particular species.

In one further example, the wavelength is 1064 nanometers +/−1 nanometers. Such a wavelength can be provided by an Nd:YAG laser source of 430 mW power rating, for example. The wavelength of 1064 nanometers is especially suitable for the manganese electrolytes discussed above. At other, lower wavelengths, the manganese species fluoresce over a wide range of wavelengths that thus create substantial noise that makes it more difficult to discern wavelength bands of interest. At 1064 nanometers, however, fluorescence is minimized, thereby enabling a higher resolution of the wavelengths of interest.

The analysis module 40b includes a detector that receives the Raman scatter and generates an electric signal in proportion to the wavelength and intensity, which represents the spectrometer data. Based on the spectrometer data, the analysis module 40b determines the concentration and SOC of the electrolyte 34 or 36. For example, the analysis module 40b is provided with calibration data that correlates the spectrometer data to the concentration and SOC. Such calibration data can be derived from control samples of known concentrations of species that are analyzed by Raman spectroscopy to generate spectral wavelength scans of the Raman scatter response and response intensities. The scans or individual wavelengths or wavelength bands are unique in wavelength peaks and/or wavelength intensity and thus correlate to the known concentration of the control samples. Thus, when the spectrometer data is collected for the electrolyte 34 or 36, it is entered into the correlation generated by the control samples and concentration and SOC values are measured. As will be appreciated, the spectrometer data and the calibration data may be used directly for these purposes, but derivations thereof into other meaningful data may alternatively be used. The spectrometer data and the calibration data may thus refer to the data itself or the derivation of the data.

The RFB 20 also demonstrates an example of a method, for example a method of maintaining health of the RFB 20. For instance, during operation of the RFB 20 to charge or discharge electrical energy, the Raman spectrometer 38 is used to collect the spectrometer data from one of the electrolytes 34/36 as discussed above. The spectrometer data is then compared to the calibration data to determine the SOC. Based on the SOC, a determination is made of whether to perform rebalance activities on the RFB 20. For example, a threshold SOC may be established, beyond which rebalance is to be performed. The manner of the rebalance is not particularly limited. Known rebalance techniques may be utilized, such as but not limited to, chemical treatment with an oxidant or reductant, electrochemical treatment in a rebalance cell, or addition of make-up chemicals.

The Raman spectrometer 38 provides the ability to determine SOC for species that may not otherwise be amenable to ultraviolet-visible absorbance spectroscopy. Moreover, selection of the proper wavelength of laser for a given set of species can facilitate the reduction of background noise and thus enable high resolution measurements. In addition, the SOC analysis can be conducted in situ and nearly instantaneously on-demand, without a need to shut down the RFB.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from this disclosure. The scope of legal protection given to this disclosure can only be determined by studying the following claims.

What is claimed is:

1. A redox flow battery comprising:
a cell having first and second electrodes and an ion-exchange layer arranged there between;
first and second circulation loops fluidly connected with, respectively, the first and second electrodes;
first and second electrolyte storage tanks in, respectively, the first and second circulation loops;
first and second electrolytes contained in, respectively, the first and second circulation loops; and
a Raman spectrometer on at least one of the first or second circulation loops for determining a state-of-charge of at least one of the first or second electrolytes, the Raman spectrometer including a laser source that is rated to emit a laser of a wavelength of 694 nanometers to 1444 nanometers.

2. The redox flow battery as recited in claim 1, wherein the first electrolyte is a manganese electrolyte, the second electrolyte is a polysulfide electrolyte, and the Raman spectrometer is on the first circulation loop.

3. The redox flow battery as recited in claim 2, wherein the wavelength is 1064 nanometers +/−1 nanometers.

4. The redox flow battery as recited in claim 1, wherein the Raman spectrometer includes a probe on at least one of the first or second circulation loops.

5. The redox flow battery as recited in claim 1, wherein the Raman spectrometer includes a control module that is configured to collect spectrometer data and determine from the spectrometer data the state-of-charge of at least one of the first or second electrolytes.

6. The redox flow battery as recited in claim 5, wherein the control module is configured with calibration data that provides a correlation between the spectrometer data and concentration and state-of-charge.

7. The redox flow battery as recited in claim 1, wherein the cell has an inlet side where the first and second circulation loops feed, respectively, the first and second electrolytes into the cell, an outlet side where the first and second electrolytes discharge from the cell into, respectively, the first and second circulation loops feed, and the Raman spectrometer is located on the outlet side of the cell.

8. The redox flow battery as recited in claim 1, wherein the first electrolyte is a manganese electrolyte, the second electrolyte is a polysulfide electrolyte, the Raman spectrometer is on the first circulation loop, the Raman spectrometer includes a probe on the first circulation loop, the Raman spectrometer includes a laser source that is rated to emit a laser of a wavelength of 1064 nanometers +/−1 nanometers, the cell has an inlet side where the first and second circulation loops feed, respectively, the first and second electrolytes into the cell, the cell has an outlet side where the first and second electrolytes discharge from the cell into, respectively, the first and second circulation loops feed, and the probe is located on the outlet side of the cell.

9. A method comprising:
during operation of a redox flow battery (RFB) to charge or discharge electrical energy, using a Raman spectrometer to collect spectrometer data from an electrolyte in the RFB, the Raman spectrometer includes a laser source that is rated to emit a laser of a wavelength of 694 nanometers to 1444 nanometers;
comparing the spectrometer data to calibration data to determine a state-of-charge of the electrolyte; and
based on the state-of-charge, determining whether to perform a rebalance on the RFB.

10. The method as recited in claim 9, wherein the RFB includes:
a cell that has first and second electrodes and an ion-exchange layer arranged there between,
first and second circulation loops fluidly connected with, respectively, the first and second electrodes,
first and second electrolyte storage tanks in, respectively, the first and second circulation loops,
the electrolyte is contained in the first circulation loop, and
the Raman spectrometer is on the first circulation loop.

11. The method as recited in claim 10, wherein the Raman spectrometer includes a probe on at least one of the first or second circulation loops.

12. The redox flow battery as recited in claim 11, wherein the cell has an inlet side where the first and second circulation loops feed, respectively, the first and second electrolytes into the cell, an outlet side where the first and second electrolytes discharge from the cell into, respectively, the first and second circulation loops feed, and the Raman spectrometer is located on the outlet side of the cell.

13. The method as recited in claim 10, wherein the electrolyte is a manganese electrolyte.

14. The method as recited in claim 10, wherein the wavelength is 1064 nanometers +/−1 nanometers.
